(19) United States
(12) Patent Application Publication
(10) Pub. No.: US 2017/0162747 A1
(43) Pub. Date: Jun. 8, 2017

(54) LIGHT-EMITTING ELEMENT AND LIGHT-EMITTING ELEMENT ASSEMBLY

(71) Applicant: SONY CORPORATION, TOKYO (JP)

(72) Inventors: HIDEKAZU AOYAGI, MIYAGI (JP); TAKAHIRO ARAKIDA, MIYAGI (JP); TAKAHIKO KAWASAKI, MIYAGI (JP); TAKAHIRO KOYAMA, MIYAGI (JP); KATSUTOSHI ITOU, MIYAGI (JP); MAKOTO NAKASHIMA, MIYAGI (JP)

(21) Appl. No.: 15/320,428

(22) PCT Filed: May 15, 2015
(86) PCT No.: PCT/JP2015/063986

§ 371 Date: Dec. 20, 2016

(30) Foreign Application Priority Data
Jul. 3, 2014 (JP) 2014-137343

(51) Int. Cl. H01L 33/20; H01L 33/58

(52) U.S. Cl. CPC H01L 33/20; H01L 33/58; H01L 33/30

(57) ABSTRACT

The light-emitting element of the present disclosure has a constant light emission intensity over a specific range of emission angle of light emitted from the center of its main light-emitting surface.

### CROSS REFERENCE TO RELATED APPLICATIONS

This application is a U.S. National Phase of International Patent Application No. PCT/JP2015/063986 filed on May 15, 2015, which claims priority benefit of Japanese Patent Application No. JP 2014-137343 filed in the Japan Patent Office on Jul. 3, 2014. Each of the above-referenced applications is hereby incorporated herein by reference in its entirety.

### TECHNICAL FIELD

The present disclosure relates to a light-emitting element and a light-emitting element assembly.

### BACKGROUND ART

The light emission intensity of a light-emitting element including a conventional light-emitting diode (LED) has a Lambertian distribution as shown in FIG. 8. In other words, the light emission intensity at emission angle (radiation angle) θ decreases according to cos(θ). By the way, in the process of mounting a light-emitting element on a mounting substrate using solder or other means for electrical bonding, inclination of the light-emitting element in an undesired direction can often occur with a certain probability. In other words, the normal line NL₁ to the mounting substrate can be non-parallel to the normal line NL₂ to the main light-emitting surface of the light-emitting element (see FIG. 9). In such a case where the “parallelism” cannot be maintained in the mounting process, for example, light emitted from the light-emitting element may fail to reach any light-receiving element. In other words, when optical signals are transmitted and received between the light-emitting element and the light-receiving element, the intensity of optical signals received by the light-receiving element may change, which may interfere with the normal transmission and receipt of signals. Methods capable of reliably mounting light-emitting elements, particularly, very small light-emitting elements with high positional accuracy on a mounting substrate without undesired events such as displacement of light-emitting elements to undesired locations and inclination of light-emitting elements are well known, for example, from Japanese Patent Application Laid-Open No. 2008-122681.

### CITATION LIST

### Patent Document

Patent Document 1: Japanese Patent Application Laid-Open No. 2008-122681

Patent Document 2: Japanese Patent Application Laid-Open No. 2011-211082

### SUMMARY OF THE INVENTION

### Problems to be Solved by the Invention

However, in order for the normal line NL₂ to the main light-emitting surface of a light-emitting element to be kept parallel to the normal line NL₁ to amounting substrate, the conventional method for mounting the light-emitting element requires controlling various mounting conditions, such as the amount and thickness of an adhesive or a solder layer used to fix the light-emitting element on the mounting substrate, the pressure during the mounting of the light-emitting element on the mounting substrate, and the number, area, and shape of the bonded parts (attached parts). In particular, the conventional method has low mass productivity when a plurality of light-emitting elements are simultaneously mounted to form an array. In Japanese Patent Application Laid-Open No. 2011-211082, the description of the conventional art shows that the light emission intensity of a light-emitting element changes depending on the presence or absence of a condenser lens. When a condenser lens is provided, the tendency of the light emission intensity at emission angle θ differs from the tendency to decrease according to cos(θ). However, the provision of a condenser lens to the light-emitting element leads to the problem of an increase in the manufacturing cost of the light-emitting element or a complicated process.

It is therefore an object of the present disclosure to provide a light-emitting element having a composition or structure that is substantially less likely to cause problems even when the normal line to the main light-emitting surface of the light-emitting element is not parallel to the normal line to amounting substrate in the process of mounting the light-emitting element on the mounting substrate, and to provide a light-emitting element assembly having such a light-emitting element.

### Solutions to Problems

To achieve the object, the present disclosure provides a light-emitting element having a constant light emission intensity over a specific range of emission angle of light emitted from the center of its main light-emitting surface.

To achieve the object, the present disclosure provides a light-emitting element assembly including:

a light-emitting element having a constant light emission intensity over a specific range of emission angle of light emitted from the center of its main light-emitting surface; and

a mounting substrate on which the light-emitting element is mounted.

### Effects of the Invention

The light-emitting element of the present disclosure or the light-emitting element in the light-emitting element assembly of the present disclosure has a constant light emission intensity over a specific range of emission angle of light emitted from the center of its main light-emitting surface. Therefore, even when the normal line to the main light-emitting surface of the light-emitting element is not parallel to the normal line to a mounting substrate in the process of mounting the light-emitting element on the mounting substrate, in other words, even when the light-emitting element is mounted in an inclined manner on the mounting substrate, the intensity of light emitted from the light-emitting element to the outside, for example, in a direction parallel to the normal line to the mounting substrate can be kept constant, which can eliminate the need to control various mounting conditions in the process of mounting the light-emitting element on the mounting substrate and can improve mass productivity. In addition, no condenser lens needs to be provided. It will be understood that the effects described herein are illustrative only and not intended to be limiting or exclude additional effects.

### BRIEF DESCRIPTION OF DRAWINGS

FIG. 1A is a schematic cross-sectional view of a light-emitting element according to Example 1, and FIG. 1B is a graph showing the light emission intensity of the light-emitting element of Example 1.

FIG. 2 is a schematic diagram showing the relationship between the light-emitting element of Example 1, a light-receiving element, and optical signal intensity in a case where the light-emitting element is mounted on a mounting substrate without being inclined.

FIG. 3 is a schematic diagram showing the relationship between the light-emitting element of Example 1, a light-receiving element, and optical signal intensity in a case where the light-emitting element is inclined by an angle θ₁ when mounted on amounting substrate.

FIGS. 4A and 4B are schematic partial cross-sectional views of a production substrate and other components for illustrating a method for producing the light-emitting element of Example 1.

FIG. 5 is a schematic cross-sectional view of a light-emitting element according to Example 3.

FIGS. 6A, 6B, and 6C are schematic cross-sectional views of light-emitting elements according to Example 4.

FIGS. 7A and 7B are schematic cross-sectional views of light-emitting elements according to Example 6.

FIG. 8 is a graph showing the light emission intensity (Lambertian distribution) of a light-emitting element including a conventional light-emitting diode.

FIG. 9 is a schematic diagram showing the relationship between a conventional light-emitting element, a light-receiving element, and optical signal intensity in a case where the light-emitting element is inclined by an angle θ₁ when mounted on amounting substrate.

FIG. 10 is a schematic diagram of light emitted from the top and side surfaces of a light-emitting element.

### MODE FOR CARRYING OUT THE INVENTION

Hereinafter, the present disclosure will be described on the basis of examples with reference to the drawings. It will be understood that the examples are not intended to limit the present disclosure and various values and materials in the examples are by way of example only. Note that descriptions will be provided in the following order.

1. Description of general features of light-emitting element and light-emitting element assembly of the present disclosure

2. Example 1 (light-emitting element and light-emitting element assembly of the present disclosure)

3. Example 2 (modification of Example 1 (optical interference effect))

4. Example 3 (modification of Example 1 (surface texture effect))

5. Example 4 (modification of Example 1 (light absorption or reflection effect))

6. Example 5 (modification of Example 1 (light guide effect))

7. Example 6 (modification of Example 1)

8. Others

[Description of General Features of Light-Emitting Element and Light-Emitting Element Assembly of the Present Disclosure]

The light-emitting element of the present disclosure or the light-emitting element in the light-emitting element assembly of the present disclosure (hereinafter, these light-emitting elements are collectively called the “light-emitting element and the like of the present disclosure”) preferably satisfies

0.7≦Iₘᵢₙ/Iₘₐₓ≦1.3,

wherein Iₘₐₓ is the maximum intensity of light emission in a specific range of emission angle, and Iₘᵢₙ is the minimum intensity of light emission in the specific range of emission angle.

The light-emitting element assembly of the present disclosure including the above preferred mode preferably satisfies

θ₁−θ₀≦70 degrees,

wherein θ₀ is a specific angle, and θ₁ is an angle between a normal line NL₁ to the mounting substrate and a normal line NL₂ to the main light-emitting surface of the light-emitting element. In addition, the light-emitting element assembly of the present disclosure including the preferred mode mentioned above may further include a light-receiving element provided to receive light emitted from the light-emitting element.

In the light-emitting element and the like of the present disclosure including the various preferred modes mentioned above, the light-emitting element may have a multilayer structure including

a first compound semiconductor layer of a first conductivity type,

an active layer, and

a second compound semiconductor layer of a second conductivity type different from the first conductivity type, and

the main light-emitting surface of the light-emitting element may include a surface parallel to the plane of lamination of the compound semiconductor layers in the multilayer structure (specifically, may include the top surface of the second compound semiconductor layer or the bottom surface of the first compound semiconductor layer). In such a preferred mode,

the multilayer structure may also have a side surface as a sub light-emitting surface,

in which light may also be emitted from the side surface. Additionally, in such a mode,

the light emission intensity may be controlled on the basis of

control of the intensity of light emitted from the main light-emission surface,

control of the intensity of light emitted from the sub light-emitting surface, or

control of the intensity of light emitted from the main and sub light-emitting surfaces. Alternatively,

the side surface may be tilted, and

the light emission intensity may be controlled on the basis of the tilt angle of the side surface. The light-emitting element and the like of the present disclosure with these configurations may further satisfy

0.1≦(the intensity of light emitted from the main light-emitting surface)/(the intensity of light emitted from the sub light-emitting surface)≦2.

In the light-emitting element and the like of the present disclosure including the various preferred modes or configurations mentioned above, the light emission intensity may be controlled on the basis of the product of the area of the light-emitting surface and the light extraction efficiency. In this case, the light extraction efficiency may be controlled on the basis of at least one effect selected from the group consisting of an optical interference effect, a surface texture effect, a light absorption or reflection effect, a light guide effect, a photonic crystal effect, and an optical fiber effect. In this regard, for example, when a light shielding member such as a light shielding electrode is formed on the light-emitting surface, the area of the light-emitting surface refers to the area of the part capable of substantially emitting light, which excludes the area of the light shielding member.

The optical interference effect for the control of the light extraction efficiency is the effect of changing the efficiency of light extraction from the light-emitting surface by forming an insulating layer on the light-emitting surface so that light passing through the insulating layer can undergo interference on the basis of the thickness of the insulating layer and the material constituting the insulating layer. The surface texture effect is the effect of changing the efficiency of light extraction from the light-emitting surface by roughening the light-emitting surface. The light absorption or reflection effect is the effect of changing the efficiency of light extraction from the light-emitting surface by forming a light absorbing or reflecting layer on the light-emitting surface so that light passing through the light absorbing or reflecting layer can change in quantity. The light guide effect is the effect of guiding and confining light in the light-emitting element by forming a half-mirror layer on the light-emitting surface or the effect of radiating light in desired directions by forming a half-mirror layer on the light-emitting surface. The photonic crystal effect is the effect of changing the effect of extraction of light at a specific wavelength by forming, adjacent to the multilayer structure, a nanostructure having periodically changing refractive indices in the inside so that the transmission of light through the nanostructure can be controlled. The optical fiber effect is the effect of transmitting light to a high-refractive-index part on the basis of total reflection or refraction at the interface between the multilayer structure and a material layer that is formed adjacent to the multilayer structure and has a refractive index different from that of the multilayer structure.

Moreover, in the light-emitting element and the like of the present disclosure including the various preferred modes or configurations mentioned above, the light-emitting element may include a light-emitting diode (LED). In this regard, the light-emitting element may have a face-up structure, in which the generated light is emitted from the second compound semiconductor layer side to the outside, or a flip-chip structure, in which the generated light is emitted from the first compound semiconductor layer side to the outside.

In the light-emitting element assembly of the present disclosure, the mounting substrate may be a semiconductor substrate, any of printed boards including rigid printed wiring boards and flexible printed wiring boards, or a lead frame. Alternatively, the mounting substrate may also be a substrate including a glass substrate and wiring formed thereon, or a TFT substrate (a substrate with tin film transistors (TFTs) formed thereon). The light-emitting element may be mounted on the mounting substrate using, for example, any of an adhesive, a conductive paste, solder, or plating.

Further, the light-receiving element may be any of a semiconductor light-receiving element and an array of semiconductor light-receiving elements. The light-receiving element may also be a drawing device such as a photosensitive drum.

Examples of materials that may be used to form the multilayer structure include GaN compound semiconductors (including AlGaN mixed crystals, AlGaInN mixed crystals, or GaInN mixed crystals), GaInNAs compound semiconductors (including GalnAs mixed crystals or GaNAs mixed crystals), AlGaInP compound semiconductors, AlAs compound semiconductors, AlGaInAs compound semiconductors, GaAs compound semiconductors, AlGaAs compound semiconductors, GalnAs compound semiconductors, GaInAsP compound semiconductors, GaInP compound semiconductors, GaP compound semiconductors, InP compound semiconductors, InN compound semiconductors, and AlN compound semiconductors. Examples of n-type impurities which may be added to the compound semiconductor layer include silicon (Si), selenium (Se), germanium (Ge), tin (Sn), carbon (C), and titanium (Ti). Examples of p-type impurities which may be added to the compound semiconductor layer include zinc (Zn), magnesium (Mg), beryllium (Be), cadmium (Cd), calcium (Ca), barium (Ba), and oxygen (O). The active layer may include a single compound semiconductor layer or may have a single quantum well structure (SQW structure) or a multiple quantum well structure (MQW structure). Methods for forming (methods for depositing) various compound semiconductor layers including active layers include metalorganic chemical vapor deposition (MOCVD or MOVPE), metalorganic molecular beam epitaxy (MOMBE), hydride vapor phase epitaxy (HVPE) in which halogen contributes to transportation or reaction, and plasma-assisted physical vapor deposition (PPD).

Raw materials for use in MOCVD for forming the compound semiconductor layers include those well known in the art, such as trimethylgallium (TMG), triethylgallium (TEG), trimethylaluminum (TMA), trimethylindium (TMI), and arsine (AsH₃). The nitrogen source gas may be, for example, ammonia gas or hydrazine. In addition, for example, for doping with silicon (Si) as an n-type impurity (n-type dopant), monosilane (SiH₄) may be used as a Si source, and for doping with selenium (Se) as an n-type impurity (n-type dopant), H₂Se may be used as a Se source. On the other hand, for doping with magnesium (Mg) as ap-type impurity (p-typedopant), cyclopentadienylmagnesium, methylcyclopentadienylmagnesium, or biscyclopentadienyl magnesium (Cp₂Mg) may be used as a Mg source, and for doping with zinc (Zn) as a p-type impurity (p-type dopant), dimethylzinc (DMZ) may be used as a Zn source. In this regard, examples of n-type impurities (n-type dopants) other than Si and Se include Ge, Sn, C, and Ti, and examples of p-type impurities (p-type dopants) other than Mg and Zn include Cd, Be, Ca, Ba, and O. In addition, examples of raw materials that may be used to produce red light-emitting elements include trimethylaluminum (TMA), triethylaluminum (TEA), trimethylgallium (TMG), triethylgallium (TEG), trimethylindium (TMI), triethylindium (TEI), phosphine (PH₃), arsine, dimethylzinc (DMZ), diethylzinc (DEZ), H₂S, hydrogen selenide (H₂Se), and biscyclopentanediethylzinc.

Examples of the production substrate for use in the production of the light-emitting element include a GaAs substrate, a GaN substrate, a SiC substrate, an alumina substrate, a sapphire substrate, a ZnS substrate, a ZnO substrate, an AlN substrate, a LiMgO substrate, a LiGaO₂ substrate, a MgAl₂O₄ substrate, an InP substrate, a Si substrate, a Ge substrate, a GaP substrate, an AlP substrate, an InN substrate, an AlGaInN substrate, an AlGaN substrate, an AlInN substrate, a GaInN substrate, an AlGaInP substrate, an AlGaP substrate, an AlInP substrate, a GaInP substrate, and a substrate including any of these substrates and an underlying layer or a buffer layer formed on the surface (main surface) thereof. The light-emitting element is first formed on the production substrate. In the final form of the light-emitting element, the production substrate may be maintained on which the light-emitting element is formed, may be partially used to be effective in controlling the area of the light extraction surface, or may be removed.

The first compound semiconductor layer as a component of the multilayer structure is electrically connected to a first electrode, and the second compound semiconductor layer is formed on a second electrode. When the first and second conductivity types are an n-type and a p-type, respectively, the second electrode may be in the form of a monolayer or multilayer structure including at least one metal selected from the group consisting of palladium (Pd), nickel (Ni), platinum (Pt), gold (Au), cobalt (Co), and rhodium (Rh) (which may be in the form of alloys) (for example, a multilayer structure including a stack of a palladium layer and a platinum layer, in which the palladium layer is in contact with the second compound semiconductor layer, or a multilayer structure including a stack of a palladium layer and a nickel layer, in which the palladium layer is in contact with the second compound semiconductor layer). Alternatively, the second electrode may include a transparent conductive material such as ITO, IZO, ZnO:Al, or ZnO:B. The first electrode preferably has a monolayer or multilayer structure including, for example, at least one metal selected from the group consisting of gold (Au), silver (Ag), palladium (Pd), platinum (Pt), nickel (Ni), aluminum (Al), titanium (Ti), tungsten (W), vanadium (V), chromium (Cr), copper (Cu), zinc (Zn), tin (Sn), and indium (In) (which may be in the form of alloys). Examples of such a structure include Ti/Au, Ti/Al, Ti/Pt/Au, Ti/Al/Au, Ti/Pt/Au, Ni/Au, Ni/Au/Pt, Ni/Pt, Pd/Pt, and Ag/Pd. In this regard, the layer indicated before the slash “/” in the multilayer structure is located closer to the active layer side. This also applies to the description below. The first electrode is electrically connected to the first compound semiconductor layer. For this connection, the first electrode may be formed on the first compound semiconductor layer, or when the production substrate has electrical conductivity, the first electrode may be formed on the production substrate. If necessary, the first or second electrode (including an extended part of these electrodes) may be provided with a connection or contact part (pad part) including a multilayer metal structure composed of a stack of a bonding layer (such as a Ti or Cr layer), a barrier metal layer (such as a Pt, Ni, TiW, or Mo layer), and a metal layer having good compatibility with mounting (such as an Au layer), such as a stack of Ti, Pt, and Au layers. The first and second electrodes and the connection or contact part (pad part) may be formed by, for example, any of various PVD methods such as vacuum deposition and sputtering, various CVD methods, and plating methods.

The light-emitting element assembly of the present disclosure may be used in, for example, devices, instruments, or parts for transmitting and receiving optical signals. Specifically, the light-emitting element assembly of the present disclosure may be used in, for example, photocouplers, light sources for drum photoreceptor-type printers, light sources for scanners, light sources for optical fibers, light sources for optical disks, optical remote controllers, and optical measurement instruments. One or more light-emitting elements should be mounted on the mounting substrate. The number and type of the light-emitting elements, the way to mount (arrange) the light-emitting elements, the intervals between the light-emitting elements, and other factors may be determined depending on, for example, the specifications, applications, or functions required of the light-emitting element-equipped device. Examples of the device obtained by mounting the light-emitting element on the mounting substrate include the devices mentioned above as well as other devices such as image display devices, light-emitting element-based backlights, and lighting devices. A red light-emitting element (red light-emitting diode), a green light-emitting element (green light-emitting diode), and a blue light-emitting element (blue light-emitting diode) each including, for example, a III-V nitride compound semiconductor may be used, and a red light-emitting element (red light-emitting diode) including, for example, an AlGaInP compound semiconductor may also be used. An infrared light-emitting element (including an AlGaAs or GaAs compound semiconductor) or an invisible region ultraviolet light-emitting element (including a III-V nitride compound semiconductor) for use in motion sensors or other sensors may also be used. The device obtained by mounting the light-emitting element on the mounting substrate is also intended to include display device units arranged in a tile pattern in a display apparatus.

The use of the light-emitting element or light-emitting element assembly of the present disclosure makes it possible to maintain a certain level of light emission intensity for light-receiving elements even when the optical axis of the light-emitting element is displaced with respect to the mounting substrate during the mounting process (namely, even when the normal line NL₂ to the main light-emitting surface of the light-emitting element is not parallel to the normal line NL₂ to the mounting substrate in the process of mounting the element on the mounting substrate), in other words, even when the light-emitting element is mounted in an inclined manner on the mounting substrate. In addition, even when a plurality of (e.g., 10,000) light-emitting elements are arranged to form an array, the same level of light emission intensity can be provided for light-receiving elements directly facing them, respectively, without any special contrivance, which makes it possible to simplify a process such as controlling the light emission intensity of each light-emitting element and to achieve high mass-productivity. Thus, when a large number of light-emitting elements are mounted, for example, to form an array, the robustness of the mounting accuracy is improved, which makes it possible to significantly improve the yield and to achieve improvements in mass productivity, such as simplification of mounting operation, reduction of mounting time, and reduction of the time required for study of condition setting.

### Example 1

Example 1 relates to the light-emitting element and the light-emitting element assembly of the present disclosure.

Specifically, the light-emitting element of Example 1 includes a light-emitting diode (LED) and has a constant light emission intensity over a specific range of emission angle (radiation angle) of light emitted from the center of its main light-emitting surface.

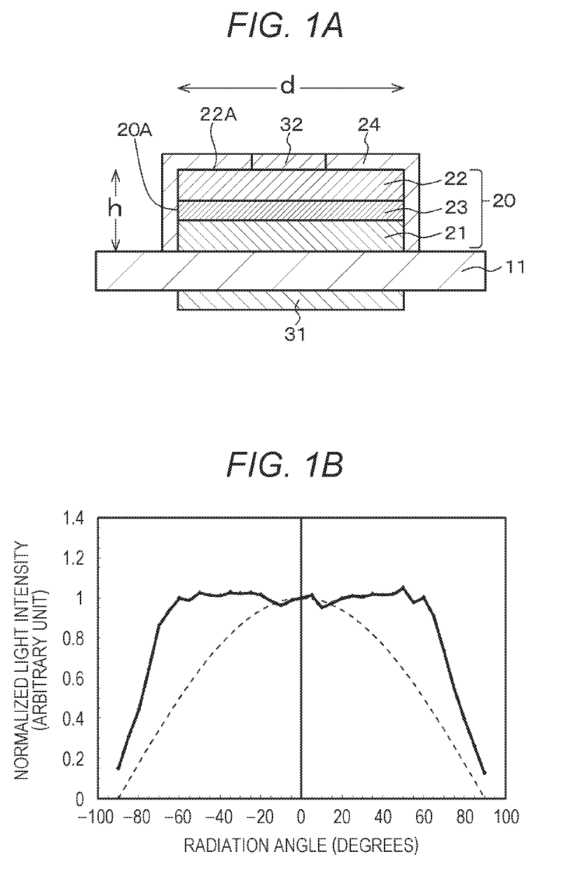

In addition, as shown in FIG. 1A, which is a schematic cross-sectional view of the light-emitting element, the light-emitting element of Example 1 has a multilayer structure 20 including a first compound semiconductor layer 21 of a first conductivity type (specifically, an n-type in the example), an active layer (light-emitting layer) 23, and a second compound semiconductor layer 22 of a second conductivity type (specifically, a p-type in the example) different from the first conductivity type. The main light-emitting surface of the light-emitting element of Example 1 includes a surface parallel to the plane of lamination of the compound semiconductor layers in the multilayer structure 20 (specifically, in Example 1, the main light-emitting surface includes the top surface 22A of the second compound semiconductor layer 22). The multilayer structure 20 also has a side surface 20A as a sub light-emitting surface, in which light is also emitted from the side surface 20A. In addition, a first electrode (n-side electrode) 31 is electrically connected to the first compound semiconductor layer 21, and a second electrode (p-side electrode) 32 is formed on the second compound semiconductor layer 22.

Specifically, in Example 1, the first electrode 31 is formed on the surface (back surface) of a production substrate 11 opposite to its surface (its main surface) in contact with the first compound semiconductor layer 21. In addition, the first compound semiconductor layer 21, the active layer 23, and the second compound semiconductor layer 22 each include a GaN compound semiconductor, specifically, AlₓGa_{y}In_{1-x-y}N (0≦X≦1, 0≦Y≦1, 0≦X+Y≦1). The first compound semiconductor layer 21 includes Si-doped GaN (GaN:Si), and the active layer 23 includes an InGaN layer (well layer) and a GaN layer (barrier layer) and has a multiple quantum well structure. In addition, the second compound semiconductor layer 22 includes Mg-doped GaN (GaN:Mg). The first electrode 31 includes, for example, a stack of a Ti layer, a Pt layer, and an Au layer, and the second electrode 32 includes a stack of a Pd layer, a Pt layer, and an Au layer. Light generated in the active layer 23 is emitted from the second compound semiconductor layer side to the outside. In other words, the light-emitting element has a face-up structure.

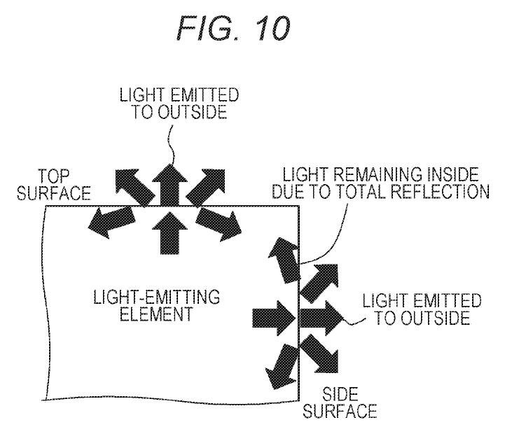

Meanwhile, the angle of emission of the light generated inside the light-emitting element is determined by the difference between the refractive index of the material constituting the light-emitting element and the refractive index of the medium (e.g., the air) outside the light-emitting element. For easy explanation, as shown in the schematic diagram of FIG. 10, the light emitted from the light-emitting element is assumed to be composed of light beams emitted from the top and side surfaces of the light-emitting element. When the light-emitting element is regarded as a single light source, the light emission intensity distribution is obtained by combining the light beams emitted from the top surface 22A of the second compound semiconductor layer 22 and from the side surface 20A of the multilayer structure 20.

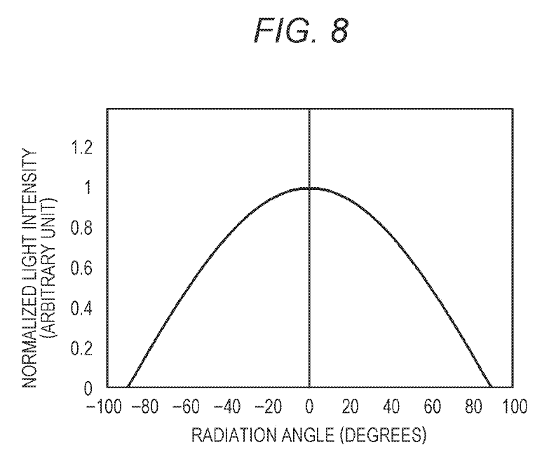

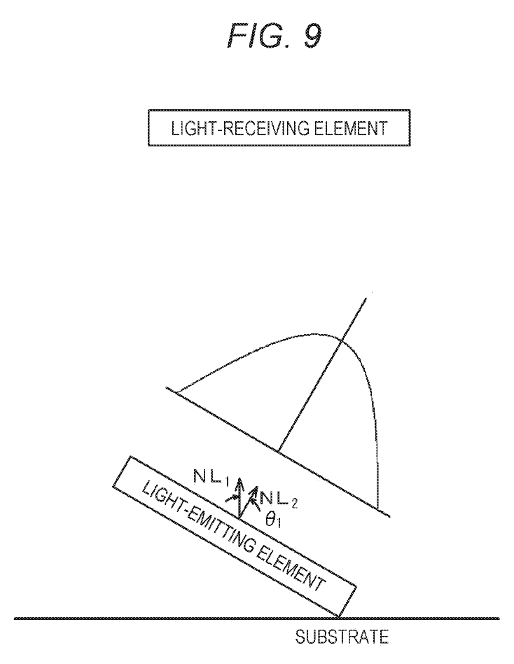

The ratio of the area of the top surface of the second compound semiconductor layer to the area of the side surface of the multilayer structure is generally about 50:1 in a conventional general light-emitting element for use in lighting and other applications. Therefore, the light emission intensity distribution substantially corresponds to the distribution of intensity of light emitted from the top surface of the second compound semiconductor layer, in other words, the Lambertian distribution shown in FIG. 8.

On the other hand, in the light-emitting element of Example 1, the light emission intensity is controlled on the basis of control of the intensity of light emitted from the main light-emitting surface and/or the intensity of light emitted from the sub light-emitting surface (light emitted from the main and sub light-emitting surfaces in Example 1). The light emission intensity is also controlled to satisfy

0.1≦(the intensity P_{M} of light emitted from the main light-emitting surface)/(the intensity P_{S} of light emitted from the sub light-emitting surface)≦2.

The light emission intensity is also controlled on the basis of the product of the area of the light-emitting surfaces and the light extraction efficiency. Specifically, Example 1 takes advantage of the fact that the light emission intensity distribution is determined by combining the light beams emitted from the main light-emitting surface (the top surface 22A of the second compound semiconductor layer 22 in Example 1) and the light beams emitted from the sub light-emitting surface (the side surface 20A of the multilayer structure 20 in Example 1). The quantity P_{M} of the light beams emitted from the main light-emitting surface and the quantity P_{S} of the light beams emitted from the sub light-emitting surface can be expressed by the formulae below. In this regard, the planar shape of the light-emitting element is a regular square.

P_{M}=S_{M}×η_{M}=d×d×η_{M}

P_{M}=S_{S}×η_{S}=d×4×h×η_{S}

In the formulae,

P_{M} is the intensity of light emitted from the main light-emitting surface (e.g., the top surface of the second compound semiconductor layer)

P_{S} is the intensity of light emitted from the sub light-emitting surface (e.g., the side surface of the multilayer structure),

S_{M} is the area of the main light-emitting surface,

S_{S} is the area of the sub light-emitting surface,

η_{M} is the efficiency of light extraction from the main light-emitting surface,

η_{S} is the efficiency of light extraction from the sub light-emitting surface,

d is the length of a side of the light-emitting element whose planar shape is assumed to be a regular square, and

h is the height of the side surface of the light-emitting element (the thickness of the multilayer structure). For example, when a light shielding member such as a light shielding electrode is formed on the light-emitting surface, the area of the light-emitting surface refers to the area of the part capable of substantially emitting light, which excludes the area of the light shielding member. When the light-emitting element has any planar shape,

S_{S}=L_{Side}×h,

wherein L_{Side} is the length of the side surface of the light-emitting element.

In Example 1,

S_{M}≈S_{S},

4h≈d, and

η_{M}≈η_{S}.

Specifically,

0.1≦S_{M}/S_{S}≦2,

0.1≦4h/d≦2, and

0.1≦η_{M}/η_{S}≦2

are satisfied in Example 1. In this case,

P_{S}/P_{M}≈1

is successfully achieved, and the light emission intensity distribution shown in FIG. 1B is successfully obtained.

Specifically,

0.7≦Iₘᵢₙ/Iₘₐₓ≦1.3

is satisfied, in which Iₘₐₓ is the maximum intensity of light emission in a specific range of emission angle (radiation angle) θ₀, and Iₘᵢₙ is the minimum intensity of light emission in the specific range of emission angle (radiation angle) θ₀. In this regard, the P_{S}/P_{M} value is determined depending on the angle (specific emission angle θ₀) at which the light-emitting element is required to have a certain desired light emission intensity. As mentioned above, the P_{S}/P_{M} value is preferably from 0.1 to 2. In Example 1, the specific emission angle (radiation angle) θ₀ is specifically 0 degrees. It will be understood that the specifications of the light-emitting element of Example 1 are not limited to the various values or numeral values given above.

In addition, the light-emitting element of Example 1 is mounted on a mounting substrate having, for example, wiring and an attachment part, by fixing the first electrode 31 to the attachment part with solder, and the second electrode 32 is further connected to the wiring. Thus, the light-emitting element assembly of Example 1 includes the light-emitting element of Example 1 and the mounting substrate on which the light-emitting element is mounted. In addition,

θ₁−θ₀≦70 degrees

is satisfied, in which θ₀ is the specific angle, and θ₁ is the angle between the normal line NL₁ to the mounting substrate and the normal line NL₂ to the main light-emitting surface of the light-emitting element.

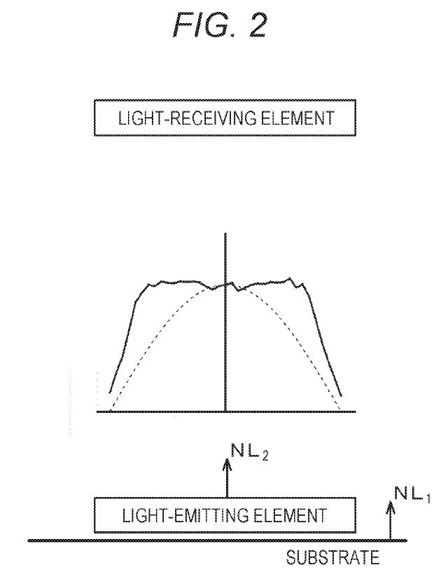

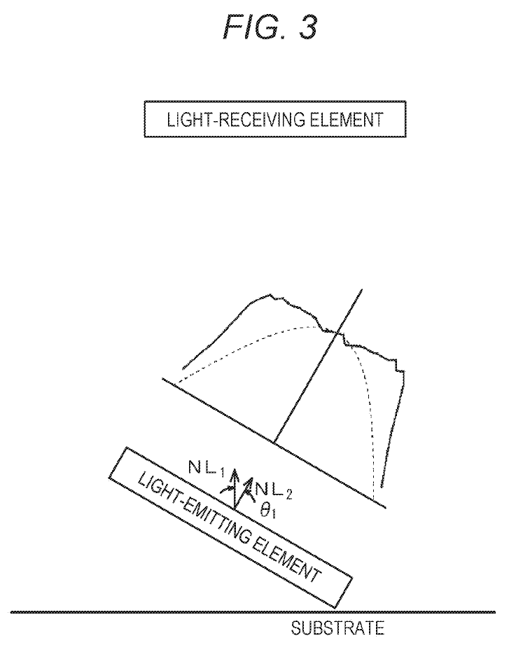

It is apparent that in the example shown in FIG. 1B, the light emission intensity per unit area does not significantly change even when the radiation direction is inclined by up to about 60 degrees, namely, even when the θ₁ value is up to 60 degrees. In other words, even when the light-emitting element with the light emission intensity shown in FIG. 1B is mounted obliquely at, for example, 60 degrees on the mounting substrate, the intensity of optical signals received by light-receiving elements can be maintained at a level similar to that when the light-emitting element mounted on the mounting substrate is not inclined (see FIGS. 2 and 3).

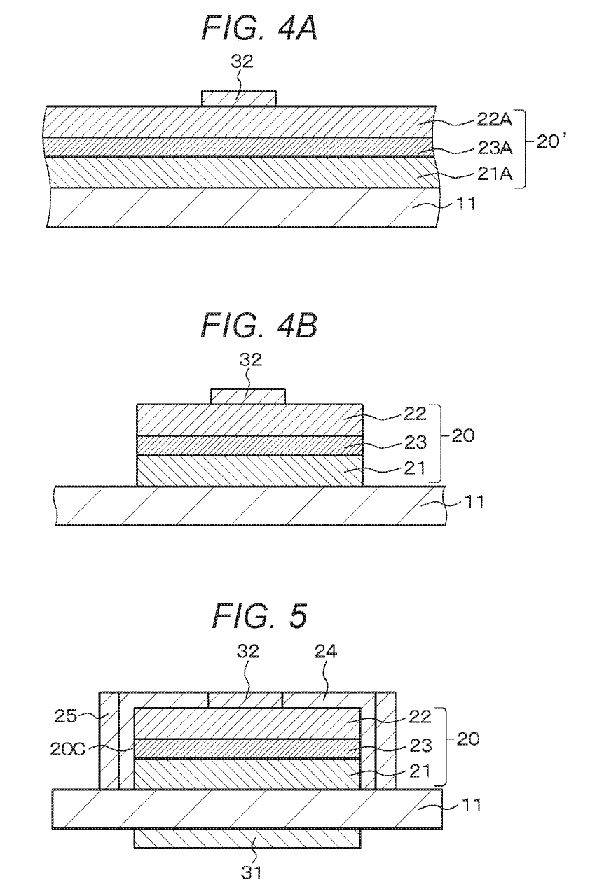

Hereinafter, the outlines of a method for producing the light-emitting element of Example 1 will be described with reference to FIGS. 4A and 4B, which are schematic partial cross-sectional views of a production substrate and other components.

[Step 100A]

First, a first compound semiconductor layer 21A of a first conductivity type, an active layer 23A, and a second compound semiconductor layer 22A of a second conductivity type different form the first conductivity type are sequentially formed on the main surface of a production substrate 11. In this regard, the alphabetical letter “A” following the reference numerals indicates that the first compound semiconductor layer 21A, the active layer 23A, and the second compound semiconductor layer 22A remain unpatterned. This also applies to the reference numeral used to indicate each layer in the description below.

Specifically, the production substrate 11, which includes an n-type GaN substrate, is fed into an MOCVD system, in which, after the substrate is subjected to cleaning at a substrate temperature of 1050° C. for 10 minutes in a hydrogen carrier gas, the substrate temperature is lowered to 500° C. Subsequently, on the basis of MOCVD, trimethylgallium (TMG) as a gallium source is supplied while ammonia gas as a nitrogen source is supplied, so that an underlying layer (not shown) including GaN is formed by crystal growth on the surface of the production substrate 11. The supply of TMG is then interrupted.

[Step 100B]

Subsequently, a multilayer structure 20′ (with a thickness h) is formed on the production substrate 11 by sequentially depositing a first compound semiconductor layer 21A of n-type conductivity, an active layer 23A, and a second compound semiconductor layer 22A of p-type conductivity.

Specifically, on the basis of MOCVD, the substrate temperature is raised to 1,020° C., and then monosilane (SiH₄) gas as a silicon source starts to be supplied, so that a first compound semiconductor layer 21A of n-type conductivity including Si-doped GaN (GaN:Si) is formed by crystal growth on the underlying layer. Note that, in this step, the doping concentration is, for example, about 5×10¹⁸/cm³.

Subsequently, the supply of TMG and SiH₄ gas is temporarily interrupted, and the substrate temperature is lowered to 750° C. Subsequently, triethylgallium (TEG) and trimethylindium (TMI) are used, and these raw materials are supplied through switching valves, so that an active layer 23A including InGaN and GaN and having a multiple quantum well structure is formed by crystal growth.

For example, a multiple quantum well structure (e.g., including two well layers) composed of InGaN with an In content of about 9% and GaN (2.5 nm and 7.5 nm in thickness, respectively) may be formed for a light-emitting diode with an emission wavelength of 400 nm. Alternatively, a multiple quantum well structure (e.g., including 15 well layers) composed of InGaN with an In content of 15% and GaN (2.5 nm and 7.5 nm in thickness, respectively) may also be formed for a blue light-emitting diode with an emission wavelength of 460 nm±10 nm. Alternatively, a multiple quantum well structure (e.g., including 9 well layers) composed of InGaN with an In content of 23% and GaN (2.5 nm and 15 nm in thickness, respectively) may also be formed for a green light-emitting diode with an emission wavelength of 520 nm±10 nm.

After the formation of the active layer 23A is completed, the supply of TEG and TMI is interrupted, and the carrier gas is switched from nitrogen to hydrogen. The substrate temperature is raised to 850° C., and TMG and biscyclopentadienyl magnesium (Cp₂Mg) start to be supplied, so that a second compound semiconductor layer 22A including Mg-doped GaN (GaN:Mg) is formed by crystal growth on the active layer 23A. Note that, in this step, the doping concentration is about 5×10¹⁹/cm³. Subsequently, the crystal growth is finished by stopping the supply of TMG and Cp₂Mg and lowering the substrate temperature to room temperature.

[Step 100C]

After the crystal growth is finished in this way, the p-type impurity (p-type dopant) is activated by annealing at about 800° C. for 10 minutes in a nitrogen gas atmosphere.

[Step 110]

Subsequently, the second electrode 32 is formed on the top surface of the second compound semiconductor layer 22A on the basis of a well-known method. In this way, the structure shown in FIG. 4A is successfully obtained.

[Step 120]

Subsequently, the multilayer structure 20′ is etched on the basis of the d value that is determined, for example, to satisfy d=4h, so that light-emitting elements are formed separate from one another. In this way, the structure shown in FIG. 4B is successfully obtained. Note that the d value may also be determined on the basis of the area (S_{M}−S_{EL2}) of the part capable of substantially emitting light, which excludes the area S_{EL2} of the second electrode 32. In other words, the area (S_{M}−S_{EL2}) of the part capable of substantially emitting light and the d and h values may be optimized by optimizing the area S_{EL2} of the second electrode 32.

[Step 130]

Subsequently, an insulating layer 24 is formed over the surface, and the first electrode 31 is formed on the back surface of the production substrate 11. Alternatively, the formation of the insulating layer 24 may be omitted. Using a blade dicer or the like, the production substrate 11 is then cut into pieces of a size suitable for mounting. Thus, the light-emitting element of Example 1 is successfully obtained, having the configurations and structure (face-up structure) shown in FIG. 1A, in which light is emitted from the second electrode side to the outside.

Note that this example may further include a substrate lamination technique for maximizing the light extraction efficiency and the step of forming an optical output-enhancing structure such as a transparent substrate structure or a reflecting structure. In this regard, the substrate lamination technique and the transparent substrate structure correspond to a technique that is used when the production substrate has the property of absorbing light from the active layer and includes bonding the light-emitting element to a transparent substrate and removing the production substrate so that light is not absorbed by the production substrate. In addition, the reflecting structure is a technique for enhancing the optical output by reflecting light from the active layer back to the inside of the light-emitting element. When the production substrate does not absorb light from the active layer, in other words, when the production substrate is transparent to light from the active layer, the entire surface of the production substrate is used as the light extraction surface, and working is performed so as to satisfy, for example,

0.1≦(the intensity P_{M} of light emitted from the main light-emitting surface)/(the intensity P_{S} of light emitted from the sub light-emitting surface)≦2

or so as to achieve a thickness and a surface area that allow the quantities P_{M} and P_{S} of light emitted from the main and sub light-emitting surfaces to satisfy the formula described above. A Bragg reflector formed using crystal growth or other techniques may also be used for the reflecting structure.

Part of the first compound semiconductor layer 21 in the multilayer structure 20 may be exposed, and the first electrode may be formed on the exposed part of the first compound semiconductor layer. In other words, the first electrode may be formed on the multilayer structure 20 side. The light-emitting element may also be formed to have a flip-chip structure capable of emitting light through the production substrate 11. In this case, the production substrate 11 itself forms the main light-emitting surface.

The light-emitting element of Example 1 has a constant light emission intensity over a specific range of emission angle (radiation angle) of light emitted from the center of the main light-emitting surface. Therefore, even when the light-emitting element is mounted on the mounting substrate in such a way that the normal line NL₁ to the mounting substrate is not parallel to the normal line NL₂ to the main light-emitting surface of the light-emitting element, namely, in such a way that the light-emitting element is mounted in an inclined manner on the mounting substrate, the intensity of light emitted from the light-emitting element to the outside can be kept constant. This makes it possible to eliminate the need for the control of various mounting conditions in the process of mounting the light-emitting element on the mounting substrate and to improve the mass-productivity.

### Example 2

Example 2 is a modification of Example 1. In Example 2, the light extraction efficiency is controlled on the basis of the optical interference effect. Specifically, in Example 2, the insulating layer 24 is a transparent layer including, for example, SiO₂ or SiN, which has high refractive index controllability. In addition, the thickness of a part of the insulating layer 24 on the side surface (sub light-emitting surface) 20A of the multilayer structure 20 is adjusted to increase the efficiency η_{S} of light extraction from the sub light-emitting surface, so that the intensity P_{S} of light emitted from the side surface (sub light-emitting surface) 20A of the multilayer structure 20 is increased. When the thickness d_{Ins} of the insulating layer 24 satisfies formula (1):

2×n_{Ins}×d_{Ins}×cos(φ)=(k+½)×λ₀ (1)

wherein d_{Ins} is the thickness of the part of the insulating layer 24 on the side surface 20A of the multilayer structure 20, n_{Ins} is the refractive index of the insulating layer 24, φ is the angle of light traveling toward the sub light-emitting surface through the multilayer structure with respect to the normal line to the sub light-emitting surface, k is a natural number, and λ₀ is the wavelength of the emitted light, the light transmitting through the part of the insulating layer 24 on the side surface (sub light-emitting surface) 20A of the multilayer structure 20 undergoes interference, which can increase the intensity P_{S} of the light emitted from the sub light-emitting surface. Thus, the light emission intensity can be controlled on the basis of control of the intensity of light emitted from the sub light-emitting surface. On the other hand, the insulating layer 24 formed on the top surface of the second compound semiconductor layer 22 may have, for example, a thickness that does not satisfy the above condition (or differs from d_{Ins}). The insulating layer 24 satisfying formula (1) may be formed over the whole or part of the side surface (sub light-emitting surface) 20A of the multilayer structure 20.

### Example 3

Example 3 is also a modification of Example 1. In Example 3, the light extraction efficiency is controlled on the basis of the surface texture effect. Specifically, as shown in the schematic cross-sectional view of FIG. 5, the side surface 20C of the multilayer structure 20 constituting the light-emitting element is roughened to produce the surface texture effect. The roughened side surface 20C causes total reflection, which reduces the amount of light remaining in the light-emitting element, so that the efficiency (η_{S}) of light extraction from the side surface 20C is improved. Thus, the light emission intensity is controlled on the basis of control of the intensity of light emitted from the sub light-emitting surface. More specifically, the side surface 20C or a rough surface layer 25 is subjected to wet etching or dry etching to form surface irregularities depending on the wavelength of light, so that the efficiency (η_{S}) of light extraction from the side surface 20C is improved. It will be understood that Example 3 may be performed in combination with Example 2. The rough surface layer 25 may be formed over the whole or part of the side surface (sub light-emitting surface) 20C of the multilayer structure 20.

### Example 4

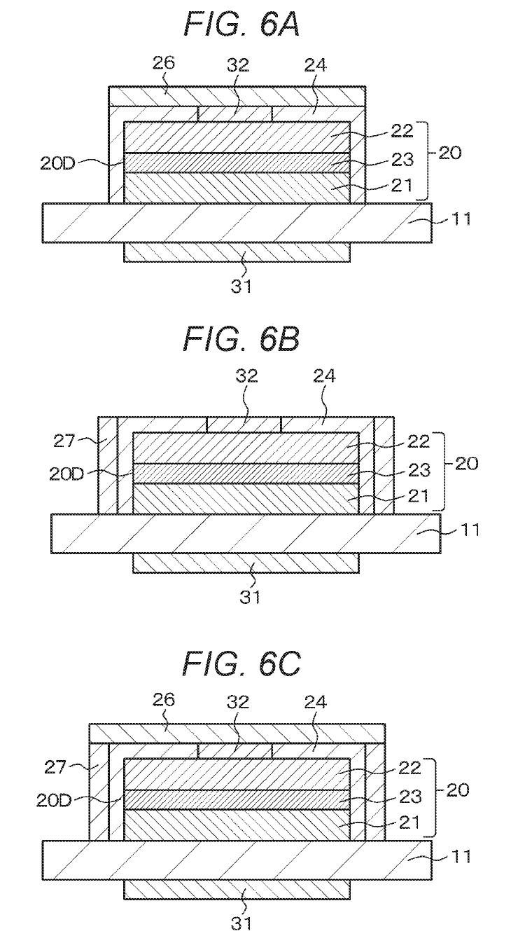

Example 4 is also a modification of Example 1. In Example 4, the light extraction efficiency is controlled on the basis of the light absorption or reflection effect. Specifically, the light-emitting element of Example 4 has a light absorbing or reflecting layer 26 that is provided on the main light-emitting surface (specifically, on the top surface of the second compound semiconductor layer 22, more specifically, as shown in the schematic cross-sectional view of FIG. 6A, on the insulating layer 24 and the second electrode 32) to partially absorb or reflect (or shield) light, so that

P_{S}/P_{M}≈1

is achieved by decreasing η_{M}. Thus, the light emission intensity is controlled on the basis of control of the intensity of light emitted from the main light-emitting surface. Specifically, the light absorbing or reflecting layer 26 may be a semi-transparent metal film, which can be obtained by controlling the thickness of a metal film that would otherwise be not transparent to light if thick. Alternatively, for example, the light absorbing or reflecting layer 26 can be obtained from an optically transparent film by using an optical interference effect to impart, to the optically transparent film, the function of reflecting light into the multilayer structure and preventing light from being radiated to the outside.

Alternatively, as shown in the schematic cross-sectional view of FIG. 6B, a light absorbing or reflecting layer 27 may also be provided on the sub light-emitting surface (specifically, on the side surface 20D of the multilayer structure 20), so that

P_{S}/P_{M}≈1

can be achieved by increasing or decreasing η_{S}. Thus, the light emission intensity may also be controlled on the basis of control of the intensity of light emitted from the sub light-emitting surface. As shown in the schematic cross-sectional view of FIG. 6C,

P_{S}/P_{M}≈1

may also be achieved by providing a light absorbing or reflecting layer 26 on the main light-emitting surface (specifically, on the top of the second compound semiconductor layer 22) and providing a light absorbing or reflecting layer 27 on the sub light-emitting surface (specifically, on the side surface 20D of the multilayer structure 20). Thus, the light emission intensity may also be controlled on the basis of control of the intensities of light emitted from the main and sub light-emitting surfaces.

The light absorbing or reflecting layer 26 may be formed over the whole or part of the main emitting surface (specifically, on the top surface of the second compound semiconductor layer 22, more specifically, on the insulating layer 24 and the second electrode 32). The light absorbing or reflecting layer 27 may be formed over the whole or part of the sub emitting surface (specifically, on the side surface 20D of the multilayer structure 20). Example 4 may also be performed in combination with Example 2.

### Example 5

Example 5 is also a modification of Example 1. In Example 5, the light extraction efficiency is controlled on the basis of the light guide effect. Specifically, the light-emitting element of Example 5 has a half-mirror layer that is formed on the main light-emitting surface (specifically, on the top surface of the second compound semiconductor layer 22, more specifically, on the insulating layer 24 and the second electrode 32 similarly to that shown in FIG. 6A) to guide and confine light in the light-emitting element and to guide light to the side surface 20D of the multilayer structure 20, so that

P_{S}/P_{M}≈1

is achieved by directly decreasing P_{M} and increasing P_{S}. Thus, the light emission intensity can be controlled on the basis of control of the intensities of light emitted from the main and sub light-emitting surfaces. Specifically, the half-mirror layer may be, for example, a semi-transparent metal film, which can be obtained by controlling the thickness of a metal film that would otherwise be not transparent to light if thick. Alternatively, for example, the half-mirror layer can be obtained from an optically transparent film by using an optical interference effect to impart, to the optically transparent film, the function of reflecting light into the multilayer structure and preventing light from being radiated to the outside. The half-mirror layer may be formed over the whole or part of the main emitting surface (specifically, on the top surface of the second compound semiconductor layer 22, more specifically, on the insulating layer 24 and the second electrode 32). Example 5 may also be performed in combination with Example 2.

Alternatively, a nanostructure having periodically changing refractive indices in the inside may be formed, so that the transmission of light through the nanostructure is controlled, which makes it possible to increase η_{S} by using the photonic crystal effect, which changes the effect of extraction of light at a specific wavelength. Specifically, the light extraction may be controlled by forming, adjacent to the multilayer structure 20, a transparent material layer having a one-, two-, or three-dimensional distribution of refractive index, for example, on the basis of CVD. Alternatively, a material layer having a refractive index different from that of the multilayer structure 20 may be formed adjacent to the multilayer structure 20, so that η_{S} can also be increased by using the optical fiber effect, which is the effect of transmitting light to a high-refractive-index part on the basis of total reflection or refraction at the interface between the multilayer structure 20 and the material layer.

### Example 6

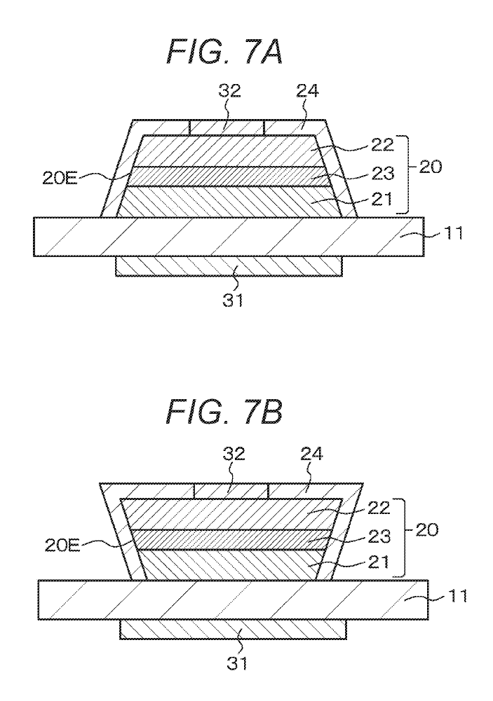

Example 6 is also a modification of Example 1. As shown in the schematic cross-sectional views of FIGS. 7A and 7B, the side surface 20E of the multilayer structure 20 in the light-emitting element of Example 6 is tilted so that the light emission intensity is controlled on the basis of the tilt angle of the side surface 20E. Thus, η_{S} is increased by tilting the side surface 20E of the multilayer structure 20. When colliding with the tilted side surface 20E, light travels in oblique directions, which changes the light emission intensity distribution. A desired radiation distribution can be obtained by controlling the tilt angle of the tilted surface. The tilted surface may form what is called a forward tapered shape (such a shape that the bottom surface area of the first compound semiconductor layer is larger than the top surface area of the second compound semiconductor layer) (see FIG. 7A) or may form what is called a reverse tapered shape (such a shape that the bottom surface area of the first compound semiconductor layer is smaller than the top surface area of the second compound semiconductor layer) (see FIG. 7B). In addition, although the tilted surface is flat in the illustrated example, the tilted surface may have a stepwise shape or irregularities. The side surface 20E (sub light-emitting surface) of the multilayer structure 20 may be entirely or partially tilted.

It will be understood that Example 6 may be performed in combination with Example 2, Example 6 may be performed in combination with Example 3, Example 6 may be performed in combination with Examples 2 and 3, Example 6 may be performed in combination with Example 4, Example 6 may be performed in combination with Examples 2 and 4, Example 6 may be performed in combination with Example 5, and Example 6 may be performed in combination with Examples 2 and 5.

Although the present disclosure has been described with reference to preferred examples, it will be understood that these examples are not intended to limit the present disclosure. The composition and structure of the light-emitting elements shown in the examples, the materials constituting the light-emitting elements, and the production conditions and various values for the light-emitting elements are by way of example only and may be changed as appropriate.

Note that the present disclosure may also have the following configurations.

### [A01] <<Light-Emitting Element>>

A light-emitting element having a main light-emitting surface, the light-emitting element having a constant light emission intensity over a specific range of emission angle of light emitted from a center of the main light-emitting surface.

[A02] The light-emitting element according to [A01], which satisfies

0.7≦Iₘᵢₙ/Iₘₐₓ≦1.3,

wherein Iₘₐₓ is the maximum intensity of light emission in the specific range of emission angle, and Iₘᵢₙ is the minimum intensity of light emission in the specific range of emission angle.

[A03] The light-emitting element according to [A01] or [A02], which has a multilayer structure including

a first compound semiconductor layer of a first conductivity type, an active layer, and

a second compound semiconductor layer of a second conductivity type different from the first conductivity type,

wherein the main light-emitting surface includes a surface parallel to the plane of lamination of the compound semiconductor layers in the multilayer structure.

[A04] The light-emitting element according to [A03], wherein

the multilayer structure has a side surface as a sub light-emitting surface, and

light is also emitted from the side surface.

[A05] The light-emitting element according to [A04], wherein the light emission intensity is controlled on the basis of

control of the intensity of light emitted from the main light-emitting surface,

control of the intensity of light emitted from the sub light-emitting surface, or

control of the intensities of light emitted from the main and sub light-emitting surfaces.

[A06] The light-emitting element according to [A04], wherein

the side surface is tilted, and

the light emission intensity is controlled on the basis of the tilt angle of the side surface.

[A07] The light-emitting element according to [A05] or [A06], which satisfies

0.1≦(the intensity of light emitted from the main light-emitting surface)/(the intensity of light emitted from the sub light-emitting surface)≦2.

[A08] The light-emitting element according to any one of [A01] to [A07], wherein the light emission intensity is controlled on the basis of the product of the area of the light-emitting surface and light extraction efficiency.
[A09] The light-emitting element according to [A08], wherein the light extraction efficiency is controlled on the basis of at least one effect selected from the group consisting of an optical interference effect, a surface texture effect, a light absorption or reflection effect, a light guide effect, a photonic crystal effect, and an optical fiber effect.
[A10] The light-emitting element according to any one of [A01] to [A09], which includes a light-emitting diode.

### [B01]<<Light-Emitting Element Assembly>>

A light-emitting element assembly including:

a light-emitting element having a main light-emitting surface, the light-emitting element having a constant light emission intensity over a specific range of emission angle of light emitted from a center of the main light-emitting surface; and

a mounting substrate on which the light-emitting element is mounted.

[B02] The light-emitting element assembly according to [B01], which satisfies

0.7≦Iₘᵢₙ/Iₘₐₓ≦1.3,

wherein Iₘₐₓ is the maximum intensity of light emission in the specific range of emission angle, and Iₘᵢₙ is the minimum intensity of light emission in the specific range of emission angle.

[B03] The light-emitting element assembly according to [B01] or [B02], which satisfies

θ₁−θ₀≦70 degrees,

wherein θ₀ is a specific angle, and θ₁ is an angle between a normal line to the mounting substrate and a normal line to the main light-emitting surface of the light-emitting element.

### REFERENCE SIGNS LIST

11 Production substrate
20, 20′ Multilayer structure
20A, 20C, 20D, 20E Side surface of multilayer structure
21, 21A First compound semiconductor layer
22, 22A Second compound semiconductor layer
23, 23A Active layer (light-emitting layer)
24 Insulating layer
25 Rough surface layer
26, 27 Light absorbing or reflecting layer
31 First electrode (n-side electrode)
32 Second electrode (p-side electrode)

1. A light-emitting element having a main light-emitting surface, the light-emitting element having a constant light emission intensity over a specific range of emission angle of light emitted from a center of the main light-emitting surface.

2. The light-emitting element according to claim 1, which satisfies
0.7≦Iₘᵢₙ/Iₘₐₓ≦1.3,
wherein Iₘₐₓ is a maximum intensity of light emission in the specific range of emission angle, and Iₘᵢₙ is a minimum intensity of light emission in the specific range of emission angle.

3. The light-emitting element according to claim 1, which has a multilayer structure comprising
a first compound semiconductor layer of a first conductivity type,
an active layer, and
a second compound semiconductor layer of a second conductivity type different from the first conductivity type,
wherein the main light-emitting surface comprises a surface parallel to a plane of lamination of the compound semiconductor layers in the multilayer structure.

4. The light-emitting element according to claim 3, wherein
the multilayer structure has a side surface as a sub light-emitting surface, and
light is also emitted from the side surface.

5. The light-emitting element according to claim 4, wherein the light emission intensity is controlled on the basis of
control of the intensity of light emitted from the main light-emitting surface,
control of the intensity of light emitted from the sub light-emitting surface, or
control of the intensities of light emitted from the main and sub light-emitting surfaces.

6. The light-emitting element according to claim 4, wherein
the side surface is tilted, and
the light emission intensity is controlled on the basis of the tilt angle of the side surface.

7. The light-emitting element according to claim 5, which satisfies
0.1≦(the intensity of light emitted from the main light-emitting surface)/(the intensity of light emitted from the sub light-emitting surface)≦2.

8. The light-emitting element according to claim 1, wherein the light emission intensity is controlled on the basis of the product of the area of the light-emitting surface and light extraction efficiency.

9. The light-emitting element according to claim 8, wherein the light extraction efficiency is controlled on the basis of at least one effect selected from the group consisting of an optical interference effect, a surface texture effect, a light absorption or reflection effect, a light guide effect, a photonic crystal effect, and an optical fiber effect.

10. The light-emitting element according to claim 1, which comprises a light-emitting diode.

11. A light-emitting element assembly comprising:
a light-emitting element having a main light-emitting surface, the light-emitting element having a constant light emission intensity over a specific range of emission angle of light emitted from a center of the main light-emitting surface; and
a mounting substrate on which the light-emitting element is mounted.

12. The light-emitting element assembly according to claim 11, which satisfies
0.7≦Iₘᵢₙ/Iₘₐₓ≦1.3,
wherein Iₘₐₓ is a maximum intensity of light emission in the specific range of emission angle, and Iₘᵢₙ is a minimum intensity of light emission in the specific range of emission angle.

13. The light-emitting element assembly according to claim 11, which satisfies
θ₁−θ₀≦70 degrees,
wherein θ₀ is a specific angle, and θ₁ is an angle between a normal line to the mounting substrate and a normal line to the main light-emitting surface of the light-emitting element.
